(19) United States
(12) Patent Application Publication
(10) Pub. No.: US 2025/0142974 A1
(43) Pub. Date: May 1, 2025

(54) POWER SEMICONDUCTOR DEVICE

(71) Applicant: Mitsubishi Electric Corporation, Tokyo (JP)

(72) Inventors: Yasuo ATA, Tokyo (JP); Tsuyoshi OSAGA, Tokyo (JP)

(73) Assignee: Mitsubishi Electric Corporation, Tokyo (JP)

(21) Appl. No.: 18/693,649

(22) PCT Filed: Oct. 1, 2021
(86) PCT No.: PCT/JP2021/036400

§ 371 Date: Mar. 20, 2024

(51) Int. Cl. H10D 89/60; H10D 64/27; H10D 64/66

(52) U.S. Cl. CPC H10D 89/611; H10D 64/513; H10D 64/661

(57) ABSTRACT

An object of the present disclosure is to provide a power semiconductor device in which a temperature sensing diode is built in a trench without losing its function as an active gate. A power semiconductor device includes, in an active region, a p-type base layer formed on an n-type drift layer, a plurality of n-type well regions formed in a front layer of the p-type base layer, and a polysilicon layer formed in each trench via an insulating film. The polysilicon layer formed in at least one trench includes an n-type polysilicon layer connected to an emitter terminal of a switching element, and a p-type polysilicon layer connected to a gate terminal of the switching element and enclosing a surface of the n-type polysilicon layer facing a side surface of the trench.

### TECHNICAL FIELD

The present disclosure relates to a power semiconductor device having a temperature sensing diode.

### BACKGROUND ART

In the power semiconductor device of Patent Document 1, a temperature sensing diode is configured by an n-type semiconductor region and a p-type semiconductor region formed inside a trench that extends through a base layer and reaches a drift region. According to the power semiconductor device of Patent Document 1, by embedding the temperature sensing diode within the trench, the temperature sensing diode can be built in in a space-saving manner, thereby enabling highly sensitive temperature monitoring.

### PRIOR ART DOCUMENTS

### Patent Document(s)

[Patent Document 1] Japanese Patent Application Laid-Open No. 2008-235600

### SUMMARY

### Problem to be Solved by the Invention

The power semiconductor device of Patent Document 1 has a problem in that the trench constituting the temperature sensing diode cannot contribute to electrical conduction as an active gate.

The present disclosure has been made to solve the above problem, and an object thereof is to provide a power semiconductor device in which a temperature sensing diode is built in a trench without losing its function as an active gate.

### Means to Solve the Problem

According to the present disclosure, a power semiconductor device includes an active region that acts as a switching element, in the active region, a drift layer of a first conductivity type, a base layer of a second conductivity type formed on the drift layer, a plurality of well regions of the first conductive type formed in a front layer of the base layer, a plurality of trenches extending through the well regions and the base layer from an upper surface of the well regions to reach the drift layer, and a polysilicon layer formed in each of the trench via an insulating film, in which the polysilicon layer formed in the at least one trench includes a first polysilicon layer of the first conductivity type connected to a main terminal of the switching element, and a second polysilicon layer connected to a control terminal of the switching element and enclosing a surface of the first polysilicon layer facing a side surface of the trench.

### Effects of the Invention

According to the power semiconductor device of the present disclosure, a temperature sensing diode is constituted by the first polysilicon layer and the second polysilicon layer formed in at least one trench. The second polysilicon layer is connected to the control terminal of the switching element and encloses the surface of the first polysilicon layer facing the side surface of the trench, so that a channel is formed in the base layer on the side surface of the trench in response to a control voltage applied from the control terminal. Therefore, the first polysilicon layer and the second polysilicon layer establish both functions as a temperature sensing diode and an active gate. The objects, features, aspects, and advantages of the present disclosure will become more apparent from the following detailed description and the accompanying drawings.

### BRIEF DESCRIPTION OF DRAWINGS

FIG. 1 A plan view of a power semiconductor device according to Embodiment 1.

FIG. 2 A perspective view of the power semiconductor device according to Embodiment 1.

FIG. 3 A circuit diagram of the power semiconductor device according to Embodiment 1.

FIG. 4 A graph illustrating the temperature dependency of the output voltage of a temperature sensing diode in the power semiconductor device of Embodiment 1.

FIG. 5 A perspective view of a power semiconductor device according to Embodiment 2.

FIG. 6 A circuit diagram of the power semiconductor device according to Embodiment 2.

FIG. 7 A perspective view of a power semiconductor device according to Embodiment 3.

FIG. 8 A circuit diagram of the power semiconductor device according to Embodiment 3.

### DESCRIPTION OF EMBODIMENT(S)

Hereinafter, the conductivity types of semiconductors will be described assuming that n-type represents the first conductivity type and p-type represents the second conductivity type. However, the conductivity types may be reversed. That is, p-type may represent the first conductivity type and n-type may represent the second conductivity type.

### A. Embodiment 1

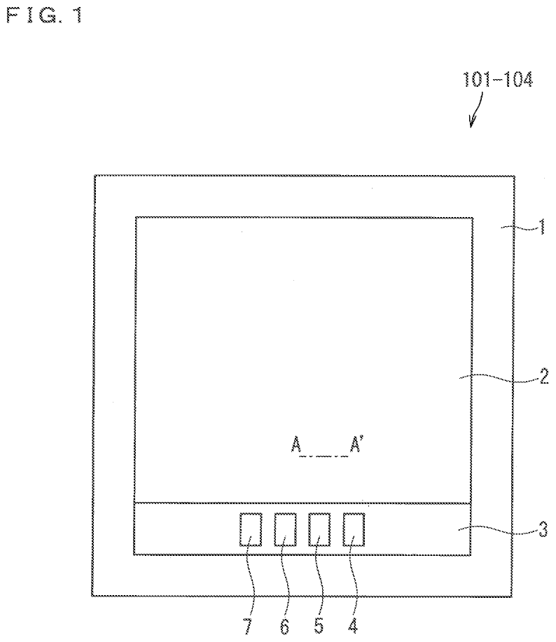

FIG. 1 is a plan view of a power semiconductor device 101 according to Embodiment 1. As illustrated in FIG. 1, the power semiconductor device 101 includes a breakdown voltage holding region 1, an active region 2, a wiring region 3, a temperature sensing cathode pad 4, a temperature sensing anode pad 5, a gate pad 6, and a Kelvin pad 7. The breakdown voltage holding region 1 encloses the active region 2 and the wiring region 3. The temperature sensing cathode pad 4, the temperature sensing anode pad 5, the gate pad 6, and the Kelvin pad 7 are formed within the wiring region 3. The active region 2 is a region where the power semiconductor device 101 operates as a switching element.

The switching element included in the power semiconductor device 101 may represent any switching element such as a Metal Oxide Semiconductor Field Effect Transistor (MOSFET), an Insulated Gate Bipolar Transistor (IGBT), or a Reverse Conducting IGBT (RC-IGBT). In the following description, it is assumed to be an IGBT.

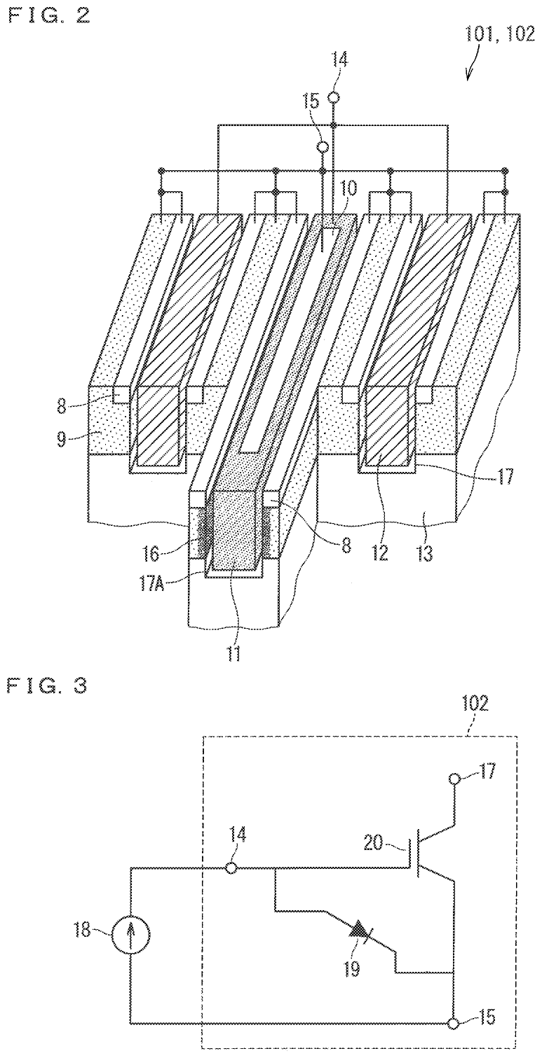

FIG. 2 is a perspective view of the active region 2 of the power semiconductor device 101. The cross section of the power semiconductor device 101 in front in FIG. 2 corresponds to the cross section taken along line A-A′ in FIG. 1, illustrating the frontal side thereof. As illustrated in FIG. 2, the power semiconductor device 101 includes, in the active region 2, an n-type drift layer 13, a p-type base layer 9, a plurality of n-type source regions 8, an n-type polysilicon layer 10, a p-type polysilicon layer 11, and a polysilicon layer 12.

The p-type base layer 9 is formed on the n-type drift layer 13. The plurality of n-type source regions 8 are formed in the front layer of the p-type base layer 9. A plurality of trenches 17, 17A extending through the n-type source regions 8 and the p-type base layer 9, and reaching the n-type drift layer 13 are formed from the upper surface of the n-type source regions 8.

A gate insulating film (not illustrated) is formed on the inner wall of the trench 17, and polysilicon layer 12 is formed inside the trench 17 via the gate insulating film. The polysilicon layer 12 acts as a gate electrode.

An insulating film (not illustrated) is formed on the inner wall of the trench 17A, and the n-type polysilicon layer 10 and the p-type polysilicon layer 11 are formed inside the trench 17 via the insulating film. The n-type polysilicon layer 10 is also referred to as a first polysilicon layer, and the p-type polysilicon layer 11 is also referred to as a second polysilicon layer. The n-type polysilicon layer 10 is obtained by doping the polysilicon layer 12 with n-type impurities. The p-type polysilicon layer 11 is obtained by doping the polysilicon layer 12 with p-type impurities. The p-type polysilicon layer 11 is formed to enclose the n-type polysilicon layer 10. The interface between the p-type polysilicon layer 11 and the n-type polysilicon layer 10 extends along the depth direction of the trench 17A. In other words, the p-type polysilicon layer 11 encloses the surface of the n-type polysilicon layer 10 facing the side surface of the trench 17A. The p-type polysilicon layer 11 contacts the n-type source regions 8 and the p-type base layer 9 on the side surface of the trench 17A via an insulating film. The p-type polysilicon layer 11 and the n-type polysilicon layer 10 constitute a temperature sensing diode.

The polysilicon layer 12 acting as a gate electrode is connected to a gate terminal 14 which is a control terminal of the switching element, and is connected to a gate drive circuit via the gate terminal 14. The gate terminal 14 is also connected to the p-type polysilicon layer 11.

The n-type source regions 8 and the p-type base layer 9 are electrically connected to an emitter terminal 15, which is the main terminal of the switching element. The emitter terminal 15 is also connected to the n-type polysilicon layer 10.

With the above configuration, when a gate voltage is applied from the gate drive circuit to the gate terminal 14 of the power semiconductor device 101, the p-type polysilicon layer 11 becomes the High side, and the n-type polysilicon layer 10 becomes the Low side. Therefore, a forward current flows through the temperature sensing diode constituted by the p-type polysilicon layer 11 and the n-type polysilicon layer 10, enabling temperature monitoring.

Further, as described above, the p-type polysilicon layer 11 is in contact with the n-type source layers 8 and the p-type base layer 9 on the side surface of the trench 17A via the insulating film; therefore, when the p-type polysilicon layer 11 becomes the High side, the p-type base layer 9 on the side surface of the trench 17A is converted to the n-type and becomes a channel 16.

Accordingly, the n-type polysilicon layer 10 and the p-type polysilicon layer 11 formed in the trench 17A establish both functions as a temperature sensing diode and an active gate.

The power semiconductor device 101 of Embodiment 1 includes the active region 2 that acts as a switching element 20. The power semiconductor device 101 includes, in the active region 2, the n-type drift layer 13, the p-type base layer 9 formed on the n-type drift layer 13, the plurality of n-type well regions 8 formed on the front layer of the p-type base layer 9, the plurality of trenches 17, 17A extending through the n-type well regions 8 and the p-type base layer 9 and reaching the n-type drift layer 13 from the upper surface of the n-type well regions 8, and the polysilicon layer formed in each trench 17, 17A via the insulating film. The polysilicon layer formed inside at least one trench 17A includes the n-type polysilicon layer 10 being a first polysilicon layer connected to the emitter terminal 15 of the switching element 20, and the p-type polysilicon layer 11 being a second polysilicon layer connected to the gate terminal 14 of the switching element 20 and enclosing the surface of the n-type polysilicon layer 10 facing the side surface of the trench 17A. According to the power semiconductor device 101, the temperature sensing diode is constituted by the n-type polysilicon layer 10 and the p-type polysilicon layer 11 in the trench 17A, so that the temperature sensing diode can be built in in a space-saving manner. Also, when a control voltage is applied to the p-type polysilicon layer 11 from the control terminal, a channel is formed in the p-type base layer 9 on the side surface of the trench 17A, so the p-type polysilicon layer 11 also acts as an active gate. Therefore, according to the power semiconductor device 101, a temperature sensing diode can be built in the trench without losing its function as an active gate.

### B. Embodiment 2

FIG. 3 is an equivalent circuit diagram that includes a power semiconductor device 102 according to Embodiment 2. A plan view and a perspective view of the power semiconductor device 102 are similar to the power semiconductor device 101 of Embodiment 1 illustrated in FIGS. 1 and 2.

As illustrated in FIG. 3, a constant current circuit 18 is connected to the gate terminal 14 of the power semiconductor device 102. In FIG. 3, the power semiconductor device 102 includes a temperature sensing diode 19 constituted by the p-type polysilicon layer 11 and the n-type polysilicon layer 10, and a switching element 20.

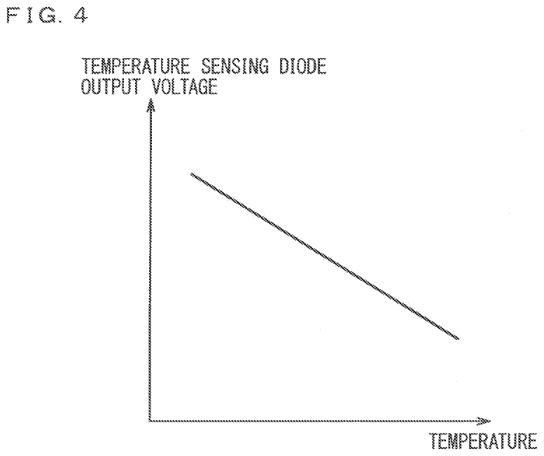

The constant current circuit 18 performs drive control of the switching element 20 of the power semiconductor device 102. By connecting the constant current circuit 18 to the gate terminal 14, the temperature sensing diode 19 of the power semiconductor device 102 exhibits a characteristic that the output voltage decreases as the temperature increases. This characteristic is illustrated in FIG. 4.

As an overcurrent flows through the switching element 20, the temperature increases and the output voltage of the temperature sensing diode 19 decreases. In the power semiconductor device 102, the output voltage of the temperature sensing diode 19 equalizes the gate voltage of the switching element 20 to the same value. This also indicates that as the output voltage of the temperature sensing diode 19 decreases, the gate voltage of the switching element 20 also decreases. As a result, overcurrent in the switching element 20 is suppressed. In this manner, the power semiconductor device 102 can establish both the overcurrent protection function and the gate drive function of the switching element 20 by the temperature sensing diode 19.

### C. Embodiment 3

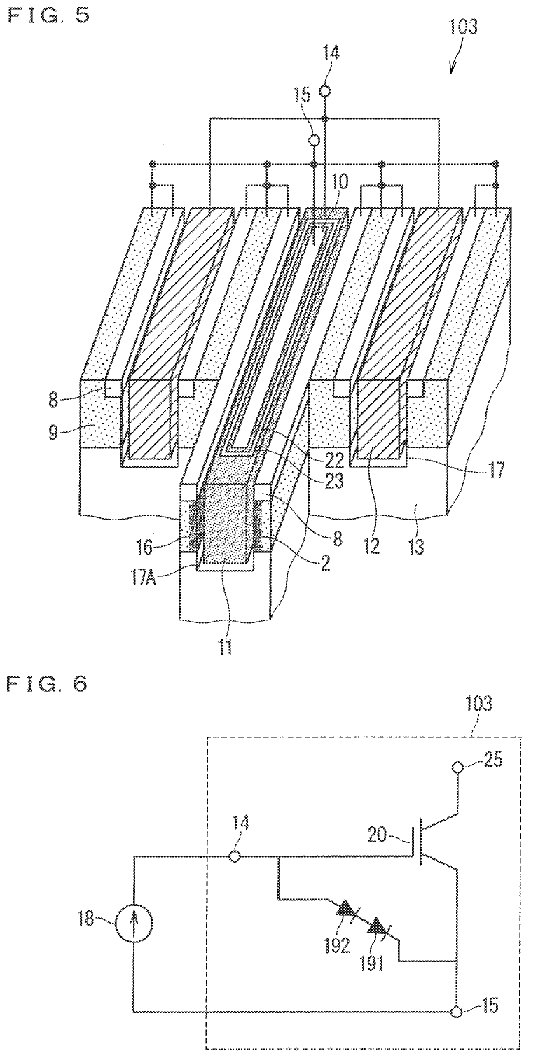

FIG. 5 is a perspective view of the active region 2 of a power semiconductor device 103 of Embodiment 3. The cross section of the power semiconductor device 103 in front in FIG. 5 corresponds to the cross section taken along line A-A′ in FIG. 1, illustrating the frontal side thereof. FIG. 6 is an equivalent circuit diagram that includes a configuration including the power semiconductor device 103. A plan view of the power semiconductor device 103 is similar to the power semiconductor device 101 of Embodiment 1 illustrated in FIG. 1.

As illustrated in FIG. 5, the power semiconductor device 103 is the one that includes a p-type polysilicon layer 22 and an n-type polysilicon layer 23 between the p-type polysilicon layer 11 and the n-type polysilicon layer 10 in the power semiconductor device 101 of Embodiment 1. The n-type polysilicon layer 23 is also referred to as a third polysilicon layer, and the p-type polysilicon layer 22 is also referred to as a fourth polysilicon layer. The p-type polysilicon layer 22 encloses the n-type polysilicon layer 10, the n-type polysilicon layer 23 encloses the p-type polysilicon layer 22, and the p-type polysilicon layer 11 encloses the n-type polysilicon layer 23. In other words, the n-type polysilicon layer 23 and the p-type polysilicon layer 22 are arranged so that n-type layers and p-type layers are alternately arranged from the p-type polysilicon layer 11 to the n-type polysilicon layer 10. The interface between the n-type polysilicon layer 10 and the p-type polysilicon layer 22, the interface between the p-type polysilicon layer 22 and the n-type polysilicon layer 23, and the interface between n-type polysilicon layer 23 and the p-type polysilicon layer 11 all extend along the depth direction of the trench 17A. The n-type polysilicon layer 23 is obtained by doping the polysilicon layer 12 with n-type impurities. The p-type polysilicon layer 22 is obtained by doping the polysilicon layer 12 with p-type impurities.

The n-type polysilicon layer 10 and the p-type polysilicon layer 22 constitute a first temperature sensing diode 191, and the n-type polysilicon layer 23 and the p-type polysilicon layer 11 constitute a second temperature sensing diode 192. As illustrated in FIG. 6, the temperature sensing diodes 191 and 192 are connected in series between the gate terminal 14 and the emitter terminal 15.

Although in the above, the power semiconductor device 103 includes two temperature sensing diodes 191 and 192 connected in series, three or more temperature sensing diodes connected in series may also be included. That is, a plurality of n-type polysilicon layers and a plurality of p-type polysilicon layers may be arranged such that the n-type layers and the p-type layers are arranged alternately from the n-type polysilicon layer 10 to the p-type polysilicon layer 11 between the n-type polysilicon layer 10 and the p-type polysilicon layer 11. The power semiconductor device 103 includes a plurality of temperature sensing diodes connected in series, this increases the gate-emitter voltage. Therefore, the switching element 20 with a high gate threshold voltage is enabled to operate.

### D. Embodiment 4

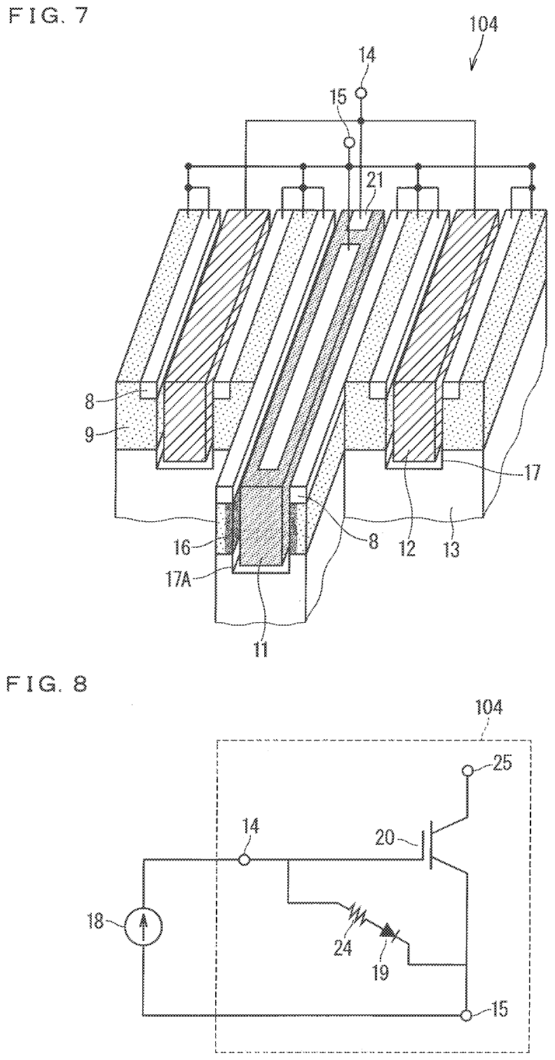

FIG. 7 is a perspective view of the active region 2 of a power semiconductor device 104 of Embodiment 4. The cross section of the power semiconductor device 104 in front in FIG. 7 corresponds to the cross section taken along line A-A′ in FIG. 1, illustrating the frontal side thereof. FIG. 8 is an equivalent circuit diagram that includes a configuration including the power semiconductor device 104. A plan view of the power semiconductor device 104 is similar to the power semiconductor device 101 of Embodiment 1 illustrated in FIG. 1.

As illustrated in FIG. 7, the power semiconductor device 104 is the one in which portion of a p-type polysilicon layer 11 is replaced with a low concentration polysilicon layer 21 with lower doping concentration than p-type polysilicon layer 11 in the power semiconductor device 101 of Embodiment 1. In other words, the p-type polysilicon layer 11 includes low concentration polysilicon layer 21 having a lower p-type impurity concentration than the remaining portion of the p-type polysilicon layer 11. And the gate terminal 14 is connected not to the p-type polysilicon layer 11 but to the low concentration polysilicon layer 21.

Accordingly, as illustrated in FIG. 8, the configuration is obtained in which the temperature sensing diode 19 and a resistor 24 constituted by the low concentration polysilicon layer 21 are connected in series in the power semiconductor device 104. The power semiconductor device 104 includes the resistor 24 connected in series to the temperature sensing diode 19, this increases the gate-emitter voltage. Therefore, the switching element 20 with a high gate threshold voltage is enabled to operate.

It should be noted that Embodiments can be arbitrarily combined and can be appropriately modified or omitted. The forgoing description is in all aspects illustrative. It is therefore understood that numerous undescribed modifications and variations can be devised.

### EXPLANATION OF REFERENCE SIGNS

1 breakdown voltage holding region, 2 active region, 3 wiring region, 4 temperature sensing cathode pad, 5 temperature sensing anode pad, 6 gate pad, 7 Kelvin pad, 8 n-type source region, 9 p-type base layer, 10, 23 n-type polysilicon layer, 11, 22 p-type polysilicon layer, 12 polysilicon layer, 13 n-type drift layer, 14 gate terminal, 15 emitter terminal, 16 channel region, 17, 17A trench, 18 constant current circuit, 19, 191, 192 temperature sensing diode, 20 switching element, 21 low concentration polysilicon layer, 24 resistor, 25 collector terminal.

1. A power semiconductor device comprising:
an active region that acts as a switching element;
in the active region,
a drift layer of a first conductivity type;
a base layer of a second conductivity type formed on the drift layer;
a plurality of well regions of the first conductive type formed in a front layer of the base layer;
a plurality of trenches extending through the well regions and the base layer from an upper surface of the well regions to reach the drift layer; and
a polysilicon layer formed in each of the trench via an insulating film, wherein
the polysilicon layer formed in the at least one trench includes
a first polysilicon layer of the first conductivity type connected to a main terminal of the switching element, and
a second polysilicon layer connected to a control terminal of the switching element and enclosing a surface of the first polysilicon layer facing a side surface of the trench.

2. The power semiconductor device according to claim 1, wherein
a constant current circuit is connected to the control terminal of the switching element.

3. The power semiconductor device according to claim 1, further comprising
at least one third polysilicon layer of the first conductivity type and at least one fourth polysilicon layer of a second conductivity type provided between the first polysilicon layer and the second polysilicon layer, wherein
the at least one third polysilicon layer and the at least one fourth polysilicon layer are arranged so that a layer of the first conductivity type and a layer of the second conductivity type to be alternated from the first polysilicon layer to the second polysilicon layer.

4. The power semiconductor device according to claim 1, wherein
the second polysilicon layer includes a low concentration polysilicon layer having a lower second conductivity impurity concentration than a remaining portion of the second polysilicon layer, and
the low concentration polysilicon layer is connected to the control terminal of the switching element.

5. The power semiconductor device according to claim 1, wherein
the switching element includes a MOSFET or an IGBT.
